(19) United States
(12) Patent Application Publication
(10) Pub. No.: US 2024/0178065 A1
(43) Pub. Date: May 30, 2024

(54) LASER DICING TO CONTROL SPLASH

(71) Applicant: TEXAS INSTRUMENTS INCORPORATED, DALLAS, TX (US)

(72) Inventors: Yang LIU, Chengdu (CN); Hao ZHANG, Chengdu (CN); Venkataramanan KALYANARAMAN, ALLEN, TX (US); Lejuan ZHOU, Chengdu (CN)

(21) Appl. No.: 18/060,305

(22) Filed: Nov. 30, 2022

(51) Int. Cl. H01L 21/78; B23K 26/06; B23K 26/53; H01L 23/00

(52) U.S. Cl. CPC H01L 21/78; B23K 26/0604; B23K 26/53; H01L 23/564; B23K 2103/56

(57) ABSTRACT

One example provides a method that includes directing a first laser beam at a surface of a semiconductor substrate along a scribe street thereof. The first laser beam is focused inside the substrate to form a first modified region, which is offset from a second modified region in a direction orthogonal to a scan direction of the first laser beam, and a first crack extending between the second modified region and the first modified region. A second laser beam is directed at the surface to form a third modified region, which is offset from the first and second modified regions, and a second crack extending from the first modified region to the surface. The first and second cracks form a zigzag-shaped crack within the substrate along the scribe street.

### TECHNICAL FIELD

This description relates generally to laser dicing to control splash.

### BACKGROUND

In semiconductor wafer processing, a step performed prior to packaging is semiconductor device die singulation. Singulation is typically accomplished either by sawing scribe streets that are formed between the semiconductor device dies on a semiconductor wafer using a saw blade or by cutting the semiconductor wafer apart along the scribe streets with a laser. Stealth dicing singulation can be used where laser energy is focused within a thickness of the semiconductor wafer. The laser energy melts the single crystalline semiconductor material and the related stress can form a crack. The crack propagates through the semiconductor wafer to enable separation of respective semiconductor device dies. In some circumstances, during stealth dicing, an incident laser beam can interact with structures within the wafer resulting in splash. Splash can cause splash-induced damage to circuitry and metal layers formed on the wafer.

### SUMMARY

One example described herein provides a method that includes directing a first laser beam at a surface of a semiconductor substrate with an entry point along a scribe street thereof. The first laser beam is focused inside the substrate to form a first modified region and a first crack. The first modified region is offset from a second modified region in a direction orthogonal to a scan direction of the first laser beam. The first crack extends between the second modified region and the first modified region along a direction orthogonal to the surface. A second laser beam is directed at the surface focused to have a second focal point inside the substrate to form a third modified region and a second crack. The third modified region is offset from the first and second modified regions in a direction orthogonal to the scan direction of the second laser beam. The second crack extends from the third modified region to the surface in a direction that is orthogonal to a scan direction of the second laser beam. The first and second cracks form a zigzag-shaped crack within the substrate along the scribe street.

Another example described herein provides a method that includes directing a first laser beam at a surface of a semiconductor substrate with an entry point along a scribe street thereof. The first laser beam is focused inside the substrate to form a first modified region and an embedded first crack, which extends from the first modified region along a direction orthogonal to the surface and having a length that is less than a thickness of the substrate. The method also includes directing a second laser beam at the surface focused to have a second focal point inside the substrate to form a second modified region, which is offset from the first modified region in a direction orthogonal to a scan direction of the second laser beam, and a second crack extending the first crack toward the surface. The method also includes directing a third laser beam at the surface focused to have a third focal point inside the substrate to form a third modified region, which is offset from the first and second modified regions, and a third crack and offset from the first crack in a direction that is orthogonal to a scan direction of the third laser beam.

Another example described herein provides a system that includes a stage, a laser system and a control system. The stage is configured to hold at least one semiconductor wafer having first and second surfaces. The wafer includes a plurality of semiconductor die having active circuitry at the second surface separated by respective scribe streets. The laser system has a laser module supported above the stage, in which the laser module configured to direct a pulsed laser beam toward the stage. The control system is coupled to the stage and the laser system. The control system is configured to control the laser system and the stage to direct a first laser beam at the first surface with an entry point along a particular scribe street thereof and focused inside the wafer to form a first modified region and an embedded crack extending from the first modified region along a direction orthogonal to the second surface. The control system is also configured to control the laser system and the stage to direct a second laser beam at the first surface along the particular scribe street focused to have a second focal point inside the wafer to form a second modified region, which is offset from the first modified region in a direction orthogonal to a scan direction of the second laser beam, and a second crack being an extension of the first crack toward the first surface. The control system is also configured to control the laser system and the stage to direct a third laser beam at the first surface along the particular scribe street focused to have a third focal point inside the wafer to form a third modified region, which is offset from the first and second modified regions, and a third crack, which offset from the first crack in a direction that is orthogonal to a scan direction of the third laser beam.

### BRIEF DESCRIPTION OF THE DRAWINGS

FIG. 1 is a depiction of an example wafer dicing system.

FIG. 2 is schematic diagram showing a partial cross-sectional view of part of a wafer showing an example three-pass laser dicing cut method.

FIG. 3 is schematic diagram showing is partial sectional view of a wafer showing an example two-pass laser dicing cut method.

FIG. 4 is photograph showing a topside view of a wafer after performing typical two-pass stealth laser dicing methods.

FIG. 5 is a photograph showing a topside view of a wafer after performing example stealth laser dicing methods.

FIG. 6 is a photograph showing a side view of a wafer after performing an example stealth laser dicing method.

FIG. 7 is a flow diagram showing an example method of stealth laser dicing.

### DETAILED DESCRIPTION

This description relates generally to systems and methods for stealth laser dicing semiconductor wafers. As described herein, the systems and methods reduce splash that can occur during stealth laser dicing particularly second pass and subsequent splash that can occur at die corners (e.g., where scribe streets intersect). In one example, more than two laser pulses are applied during two or more passes of a multi-pass stealth laser dicing cut method. The method includes offsetting a final pass of the stealth laser beam relative to beams in each of a series preceding passes to reduce interaction of the final-pass laser beam with respective modified regions formed in the preceding passes. For example, the final-pass laser beam is directed at a first surface of the die along a particular scribe street focused to have a focal point inside the wafer to form a respective modified region within the wafer at a location that is offset from a preceding modified region in a direction orthogonal to a direction the laser beam is swept across the substrate (e.g., a scan direction along a scribe street). The final-pass laser beam also forms a respective crack (e.g., microcrack) within the wafer, which is offset from one or more other cracks formed during one or more preceding passes in a direction that is orthogonal to a scan direction of the laser beam. The crack offset implemented in response to the final-pass laser beam results in a zigzag-shaped crack forming within the scribe street between respective opposing surfaces of the wafer. Additionally or alternatively, by implementing more than two laser beam passes, each of the respective passes can be implemented to form satisfactory cracks within the wafer to enable effective dicing using lower power than other approaches that use only two or fewer passes. The lower power also reduces the total splash energy, which can be absorbed by adjacent portions of the semiconductor substrate (e.g., silicon). Because the approach described herein can reduce splash, the width of the scribe streets can be reduced in wafers enabling the number of die implemented on a given die to be increased with a corresponding increase in die yields.

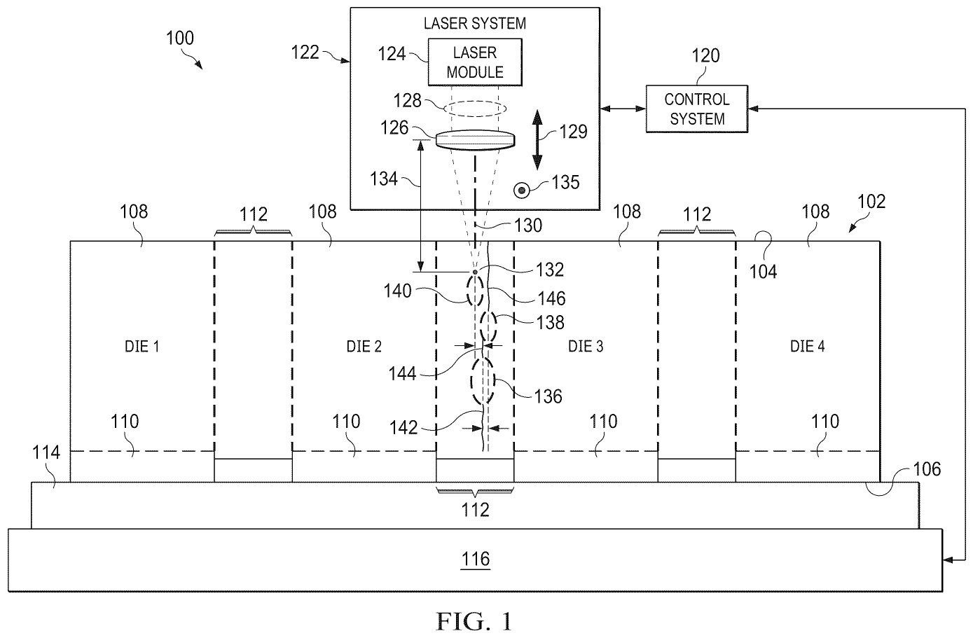

FIG. 1 depicts an example of a laser dicing system 100 configured to implement stealth laser-based dicing of a semiconductor substrate 102. The substrate 102 can be a semiconductor wafer that includes a first and second opposing side surfaces 104 and 106. For example, the first surface 104 is a bottom side (also referred to as the back side) of the wafer 102 and the second surface 106 is a top side (also referred to as the front side) of the wafer. The wafer 102 has a surface on the second side and includes a plurality of semiconductor die 108, shown as die 1, die 2, die 3, and die 4. Each die 108 has circuitry 110 formed therein at or near the surface of the second surface 106. Each of the die 108 are separated from one another by respective scribe streets 112. Thus, respective scribe streets are located between adjacent die 108.

In the example of FIG. 1, the second side surface 106 of the wafer 102 is shown on a dicing tape 114, and wafer that is mounted on a stage 116 of the dicing system 100. For example, wafer is mounted on the stage 116 after the dicing tape 114 has been applied, as shown in FIG. 1. In other examples, the dicing tape 114 can be applied to the surface of the first or second sides after laser dicing has been completed. The stage is moveable in at least two orthogonal directions parallel to the surface of the wafer (e.g., to provide movement in at least two degrees of freedom). For example, the stage 116 is moveable in five degrees of freedom, such as along three orthogonal axes as well as pitch and roll directions.

The system 100 also includes a control system 120 coupled to the stage and to a laser system 122. The control system 120 is configured to control movement of the stage along its several degrees of freedom to position the stage and a wafer 102 supported by the stage relative to the laser system 122. The control system 120 is also configured to control operation of the laser system 122 to direct an incident laser beam to perform stealth laser dicing within a given scribe street 112 as the stage is moved along a scan direction parallel to the given scribe street and orthogonal to the incident surface of the wafer 102. For example, the control system 120 controls parameters of the laser system 122 and the stage to perform stealth laser dicing for each pass of a multi-pass stealth laser dicing process, as described herein. The parameters can include pulse rate (e.g., pulse frequency), pulse pitch, feed speed, split beam distance, stage position and motion, optical wavelength, beam energy level, focal length of the beam, beam width and the like.

As schematically shown in FIG. 1, the laser system 122 includes a laser module 124. For example, the laser module 124 is configured to generate an infrared (IR) laser beam 128. The laser system 122 also includes an arrangement of optics, such as including one or more focusing lens 126. The laser module 124 includes a laser light source configured to perform pulsed oscillation of laser light along the optical axis 130 while the lens 126 is adjusted (e.g., by control system 120) to focus beam at a focal point 132 located within the wafer 102 along a respective scribe street 112. The focusing lens 126 may also be referred to as a condensing lens and move in the direction shown at 129, which is parallel to the optical axis 130, to adjust the position of the focal point of the focused laser beam. The distance between the lens 126 and the focal point 132 defines a focal length 134, which can be set to different distances (by the control system 120) during each pass of the multi-pass stealth dicing process. As used herein, a pass refers to a movement of the laser beam once across the wafer 102 along a beam scan direction within a respective scribe street 112, such as by moving the stage linearly beneath the pulsed laser beam while set to a given focal length. For example, the laser beam scan direction is shown at 135 (e.g., orthogonal to the page on which FIG. 1 is presented).

The IR laser beam 128 is provided at a wavelength capable of transmitting through the wafer 102 and is directed so that a point of entry on the first surface 104 of the wafer 102 within respective scribe streets 112. As an example, the laser module 124 is configured to pulse the IR laser beam 128 at a frequency of about 50 kHz to 200 kHz, such as 100 kHz, while the stage 116 moves the wafer 102 relative to the IR laser beam 128 with a velocity (e.g., ranging from about 0.5 m/sec to about 2 m/s). The IR laser beam 128 is scanned (e.g., linearly) across the wafer to stay within the scribe streets 112 to circumscribe each die on the wafer 102 during each pass. As a further example, the laser module 124 includes a pulsed laser (e.g., an Nd:YAG laser) outputting a wavelength of 1,064 nm. The laser module 124 is adapted for silicon dicing applications because the room temperature band gap of silicon is about 1.11 eV (1.12 nm), so that maximum laser absorption can be adjusted by optical focusing. Other types of lasers and wavelengths can be used in other examples depending on the substrate material being used.

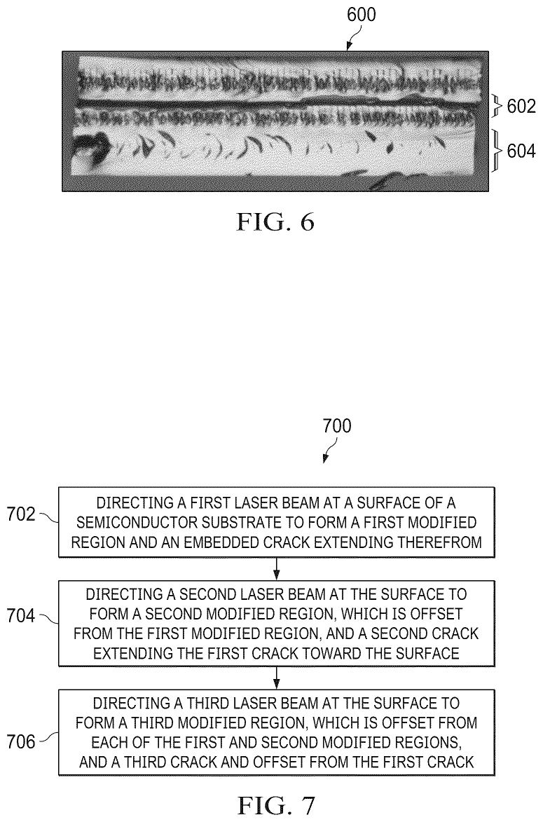

During each pass of the laser across the wafer 102, the focused beam is provided with sufficient energy to cause thermal shock at a localized damage zone at the focal point 132. The damage zone can be a volume of substrate material (e.g., silicon), which is referred to herein as a modified region (also referred to as a stealth damage region). As the beam is scanned across the wafer, a plurality of adjacent modified regions are formed at a given depth (e.g., depending on the focal length 134 of the beam scan) to provide a respective modified layer (e.g., a stealth dicing layer) within the wafer along the length of the scribe street 112. In the example of FIG. 1, three separate modified regions 136, 138 and 140 are shown, each of which can be considered to be representative of a respective modified layer embedded within the wafer 102 during a given pass of the laser beam focused at a different depth along the scribe street 112. That is, each of the modified regions 136, 138 and 140 is formed by generating the beam during a respective pass in which the laser beam has its focal point at or near the center of each region. While the modified regions 136, 138 and 140 are shown schematically as having circular or ellipsoid shapes, the modified regions typically have more unstructured shapes according to the crystalline structure and interaction between the beam and substrate materials (see, e.g., FIG. 6).

As shown in FIG. 1, the modified region 136 results from a first pass of the IR laser beam 128 is configured to be embedded within a thickness of the wafer 102 to form an embedded crack line 142. The second modified region 138 can be formed during either the first pass or during a second pass of the IR laser beam 128, in which the focal point of the laser beam is laterally offset from the first pass focal point. The energy of the laser during each pass will depend on the type and configuration of the laser and the thickness of the wafer. Additionally, the IR laser beam, which is provided to form the second modified region 138, can be provided at an energy that is lower than (e.g., about 80%) the energy for IR laser beam used to form the first modified region 136 pass. By providing the second IR laser beam at a spatial offset and lower energy relative to the first IR laser beam, the second crack line 144 can extend straight vertically from the modified region 136 (e.g., aligned vertically with crack line 142) and shallower (e.g., closer to the surface 104) as compared to the embedded crack line 142. That is, the second crack line 144 can be formed as an extension of (e.g., following the direction of) the initial crack line 142 created responsive to formation of the first modified region.

The third modified region 140 can be formed during a second or third pass of the IR laser beam 128, in which the focal point of the laser beam is spatially offset from the second pass focal point in a direction orthogonal to the scan direction. In some examples, the focal point of during the third-pass laser beam is spatially offset laterally (e.g., orthogonal to the laser beam scan direction 135) from both the first and second focal points. Additionally, the energy of the IR laser beam used to form the third modified region 140 can be lower than used to form the first modified region 136, which can be the same or different from the energy used for the second modified region 138. By providing the final pass IR laser beam at a focal point spatially offset from the beams used to form the first and second modified regions 136 and 138, the third modified region 140 is adapted to form the third crack line 146 extending straight vertically from the second modified region 138, which is spatially offset from the first crack 142 and crack extension 144. The third crack 146 can also be formed in the die at a shallower location (e.g., closer to the surface 104) as compared to the prior embedded cracks 142 and 144.

After laser dicing the wafer 102, the wafer can remain on the dicing tape 114. To separate the die, the wafer 102 and tape 114 can be transferred to a die expander apparatus to expand the die. The die expansion step connects the respective crack lines by propagating the cracks along the natural crystal cleave planes in the thickness direction of the wafer 102 to dice the wafer 102 into separate (singulated) individual semiconductor die. The wafer 102 is generally not singulated into separate semiconductor die until after die expanding is performed.

Each of the singulated semiconductor die 108 thus have sidewall surfaces (e.g., typically four sidewall surfaces) between the die surfaces 104 and 106. As a result of the laser dicing process sidewall surfaces include laterally offset first and second sidewall portions. For example, the first sidewall portion extends along crack lines 142 and 144, and the second sidewall portion extends along crack line 146. As described herein, the crack line 146 can be laterally offset from crack lines 142 and 144 by a distance ranging from 1 μm to 5 μm. Thus, the first sidewall portion is configured to extend from the side surface 106 along a direction orthogonal to the surface 106 and terminate at an intermediate location between the first and second side surfaces (e.g., at a location within or adjacent modified region 138). The second sidewall portion is laterally offset and extends from the intermediate location to the opposite side surface 104 along the same direction orthogonal to the respective surfaces. As a result of the laser dicing process described herein, the respective sidewall portions of singulated die 108 have zigzag-shaped sidewall surfaces between the top and bottom side surfaces 104 and 106.

As described herein, the respective laser beam passes are each applied at a plurality of different width/area scribe street locations in each scribe street 112 across the entire width of wafer 102 to form what may be referred to as being as pock marks. The number of pock marks formed in each scribe street 112 is generally dependent on the frequency of the laser pulse and speed with which the wafer 102 is moving during dicing. As a result of implementing a final-pass laser beam with a spatial offset, there is less interaction between the final-pass laser beam with existing cracks 142 and 144 than existing approaches, which causes reduced splash to interconnects and adjacent circuitry 110 near the scribe streets 112. Additionally, because a third modified region is formed (e.g., during a respective pass), reduced energy can be used to form each modified region (compared to typical stealth dicing). Because splash energy can be reduced, the likelihood of splash damage can be reduced increasing the overall yield of die for a given wafer.

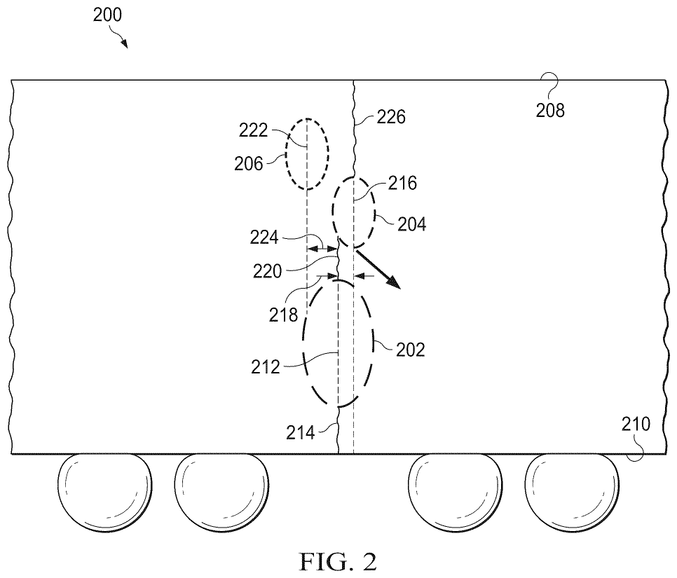

FIG. 2 is schematic diagram showing a partial cross-sectional view of part of a wafer 200 showing an example of a three-pass stealth laser dicing cut method. Each pass can be performed successively by a respective laser (e.g., laser system 122) configured to provide a series of laser pulses along a corresponding portion of the wafer 200 extending (e.g., orthogonally) between opposing side surfaces 208 and 210 with a certain thickness. In the example of FIG. 2, the laser dicing method includes a first pass with a single laser beam to form a first modified region 202, a second pass with a single laser beam to form a second modified region 204, and a third pass with a single laser beam to form a third modified region 206. The first pass includes providing a series of laser beam pulses at target positions, shown at 212, which can be aligned with a center of the scribe street. As shown in FIG. 2, the lateral position 212 of the first-pass laser beam is aligned with a crack base line 214, which extends from the first modified region 202 toward the surface 210. The second pass includes providing a second series of pulses of the laser beam at target positions, shown at 216. The target positions 216 of the second-pass laser beam are offset from focal point of the first-pass laser beam by a first offset in a direction towards the surface 208 (e.g., in the dicing direction). The target positions 216 of the second-pass laser beam are also offset laterally from (e.g., in a direction orthogonal to) the scan direction and crack base line 214. The lateral offset is shown at 218. A crack line 220 extends from the first modified region 202 to the second modified region responsive to the second-pass laser beam. The crack line 220 extending between modified regions 202 and 204 is aligned with the crack base line 214, such as shown in FIG. 2.

The third pass includes providing a third series of pulses of the laser beam at target positions, shown at 222. The target positions 222 of the third-pass laser beam are offset from focal point of both the first pass and second-pass laser beams. In the example of FIG. 2, the target positions 222 of the third-pass laser pulses are offset from the second pass focal point in a direction towards the surface 208 (e.g., in the dicing direction). The target positions 222 of the third-pass laser beam are also offset laterally from (e.g., in a direction orthogonal to) the scan direction and crack base line 214, which offset is opposite from the second-pass offset 218. The lateral offset of the third-pass pulses is shown at 224. A crack line 226 is formed responsive to the third pass pulse, which extends from the second modified region 204 in alignment with the target positions 216 of the second pass series of pulses. Thus, the crack line, which is formed responsive to the third-pass laser pulses is laterally offset from the crack lines 214 and 220 by approximately a distance of the offset 218 in a direction opposite to the dicing direction. Therefore, the first, second and third target positions 212, 216 and 222 form a zigzag feature along the crack base line through the wafer 200.

By implementing the first offset 218, as described herein, the silicon side crack line is shifted to reduce (or prevent) final pass splash energy transfer through a straight crack line so the splash energy dissipates before reaching active circuitry on the surface 210. The second offset 224 further helps to reduce interaction for final-pass laser beam with the crack lines already formed at 214 and 220.

In some examples, the power of a second beam for generating the second series of pulses is less than power of a first beam for generating the first series of pulses. The power of the third beam for generating the third series of pulses can also be equal to or less than power of the first beam. For example, the first pass include providing a pulsed first IR laser beam directed at the bottom side that is at a wavelength capable of transmitting through the semiconductor wafer with a point of entry at the scribe streets. The first IR laser beam is focused with a focal point embedded within a thickness of the wafer. The parameters for the first IR laser beam are selected so that there is an embedded crack line formed within the wafer, where the embedded crack line does not reach a surface of the top side.

The following table, Table 1, demonstrates test results of using an example three-pass proposed dicing method, such as the approach shown in FIG. 2, to cut a silicon wafer 200 with different processing parameters (or recipes). For the examples of Table 1, the offset 218 was set to 3.5 μm, and the second offset 224 was set to 3 μm. Also, 100% cracks in half cut (HC) and backside (silicon side) half cut (BHC) extend to corresponding surfaces 210 and 208 of the wafer 200. Table 1 also demonstrates results for increasing power (e.g., high power (HP)) and decreasing power (low power (LP)) of the second and third pulses by 10%, and increasing the thickness (high thickness (HT)) and decreasing the thickness (low thickness (LT)) of the wafer by 12.5 um, to test the first proposed dicing method in these extreme conditions.

TABLE 1

| Recipe | HC/BHC | HC meandering | Splash |
|---|---|---|---|
| 7 mil wafer using | 100% | Max 5.6 μm | 5/200, max 13 μm |
| approach of FIG. 2 | | | |
| HP (Power + 10%) | 100% | Max 6.6 μm | 3/200, max 12.4 μm |
| LP (Power − 10%) | 100% | Max 4.2 μm, | 1/200, max 11.1 μm |
| HT (Thickness + | 100% | Max 5.2 μm | 2/200, max 12 μm |
| 12.5 um) | | | |
| LT (Thickness − | 100% | Max 8.6 μm | 0/200, max 9.7 μm |
| 12.5 um) | | | |

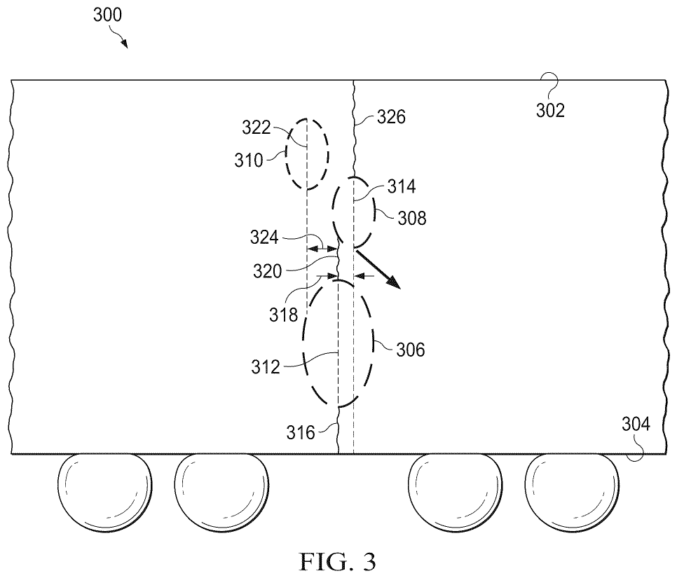

FIG. 3 is schematic diagram showing is partial sectional view of a wafer 300 showing an example two-pass stealth laser dicing cut method. The example two-pass dicing method includes two passes, namely a first pass and a second pass. In one example, the first pass includes multiple beams, such as to provide first and second series of pulses along the scribe street. The second pass includes a single beam to provide a third series of pulses along the scribe street. In another example, the first pass provides the first beam to provide a first series of laser pulses, and the second pass includes multiple beams to provide second and third series of pulses along the scribe street.

The following description of FIG. 3 is directed to the above example, in which the first pass includes the multiple beams to provide first and second series of pulses along a scribe street, each having focal points at different depths. For example, the first pass includes first and second laser beams respectively providing first and second series of laser pulses along the dicing direction apart from respective surfaces 302 and 304 within the wafer 300. The laser beams provided during the first pass thus form respective first and second modified regions 306 and 308. The second pass includes a single laser beam to provide a series of respective pulses along the dicing direction at a different depth (e.g., closes to the surface 302) to form a third modified region 310.

As an example, the first pass includes providing two series of laser beam pulses at target positions along the dicing direction, shown at 312 and 314. The target positions 312 and 314 are offset from each other in dicing direction between the surfaces 302 and 304. The target positions 312 for the series of pulses are closer to the surface 304 and form modified region 306, and can be aligned with a center of the scribe street. A corresponding crack line 316 is formed responsive the pulses forming the modified region 306. The crack line 316 can extend from the first modified region 306 towards the adjacent surface 304.

The target positions 314 for the second series of pulses, which are provided during the first pass, are spaced in the dicing direction from the surface 304 further than the target positions 312. For example, the laser system is configured to direct respective focal points of the first and second series of pulses offset from each other in the dicing direction. The target positions 314 are also offset laterally from the target positions 312 by an offset distance, shown at 318. A crack line 320 is formed extending in the dicing direction between the first and second modified regions 306 and 308 responsive to the series of pulses at target positions 314 forming the second modified region 308. The crack line 320 can extend in the dicing direction (between surfaces 302 and 304) aligned with the base crack line 316, as shown in FIG. 3.

The second pass includes a series of pulses of the laser beam at respective target positions 322. The target positions 322 of the second-pass laser beam are offset from the respective target positions 312 and 314 of both first pass pulses. In the example of FIG. 3, the target positions 322 of the second-pass pulses are offset from the target position of the second modified region 308 in the dicing direction and towards the surface 302. The target positions 322 of the second-pass laser beam are also offset laterally from (e.g., in a direction orthogonal to) the scan direction and the crack line 320. The lateral offset of the second pass pulses is shown at 324 and, in the example of FIG. 3, is in an opposite lateral direction from the second pass offset 318. In other examples, the lateral offset 324 can be in the same direction as the first pass offset 318.

A crack line 326 thus is formed responsive to the second pass pulses forming the third modified region 310. The crack line 326 extends from the second modified region 308 and is generally aligned with the target positions 316 of the second modified region 308. Thus, the crack line 326, which is formed responsive to the second-pass laser pulses, is laterally offset from the first pass crack lines 316 and 320 by approximately a distance of the offset 318 and in a direction orthogonal to the dicing direction. Therefore, the first, second and third target positions 312, 314 and 322 as well as respective crack lines 316, 320 and 326 form a zigzag feature along the crack base line along the dicing direction through the wafer 300.

By implementing the first offset 318, as described herein, the silicon side crack line is shifted to reduce (or prevent) final pass splash energy transfer through a straight crack line so the splash energy dissipates before reaching active circuitry on the surface 304. The second offset 324 further helps to reduce interaction for final-pass laser beam with the crack lines already formed at 316 and 320.

Table 2 shows test results of using the example three-pass dicing method shown in FIG. 3 to cut silicon wafers with different processing parameters. For the results shown in Table 2, the first offset 218 is set to 3.5 μm, and the second offset 224 is set to 3 μm. Also, 100% cracks in half cut (HC) and backside (silicon side) half cut (BHC) extend to corresponding surfaces 302 and 304 of the wafer 300. As described in Table 2, a maximum HC meandering is 5.6 μm, 5 splashes are found among 200 units, and the maximum distance from the base line is 13 μm. Table 2 further includes test results in other conditions, such as based on the offsets 218 and 224 configuration in the first row, further increasing or decreasing power of the second and third pulses by 10%, and based on the 218 and 224 configuration in the first row further increasing or decreasing the thickness of the wafer by 12.5 μm.

TABLE 2

| Recipe | HC/BHC | HC meandering | Splash |
|---|---|---|---|
| 7 mil - MS(Zigzag) | 100% | Max 3.8 μm | 3/200, max 12.1 μm |
| (offsets = 3.5 μm | | | |
| and 3 μm) | | | |
| HP(Power + 10%) | 100% | Max 4.3 μm | 1/200, max 10.7 μm |
| LP(Power − 10%) | 100% | Max 5.1 μm, | 2/200, max 13.8 μm |
| HT (Thickness + | 100% | Max 3.2 μm | 1/200, max 8.5 μm |
| 12.5 μm) | | | |
| LT (Thickness − | 100% | Max 6.2 μm | 4/200, max 11.9 μm |
| 12.5 μm) | | | |

A comparison between the results in Tables 1 and 2, demonstrates that the two-pass approach depicted in FIG. 3, as shown in Table 2, exhibited a decrease in maximum HC meandering. For example, the maximum HC meandering in Table 1 was 5.6 μm compared to 3.8 μm shown in Table 2. Additionally, compared to the test results shown in Table 1, the results in Table 2 had fewer splashes found among 200 units, and the maximum distance from the base line was 12.1 μm (compared to 13 μm in Table 1). Also compared to the example three-pass dicing method of FIG. 2, the example two-pass dicing method of FIG. 3 can improve dicing efficiency evaluated based on wafers per hour. However, the three-pass example of FIG. 2, enables a reduction in power for each series of pulses, which results in a corresponding reduction in total splash energy.

In each of the examples of FIGS. 2 and 3, power of the second beam pulses is equal to or less than power of the first beam pulses, and power of the third beam pulses is equal to or less than power of the first beam. The parameters used for dicing a particular wafer such as the input power, depth of the cutting and the duration of a pulse can be adjusted depending on parameters of the particular wafer, including the size and thickness of the wafer. As one example, the laser pulse input power of the first series of pulses is between 0.2 W and 0.9 W, the laser pulse input power of the second series of pulses is between 0.2 W and 0.7 W, and the laser pulse input power of the third series of pulses is between 0.2 W and 0.5 W. In one example, a duration of a laser pulse is about hundreds of nanoseconds.

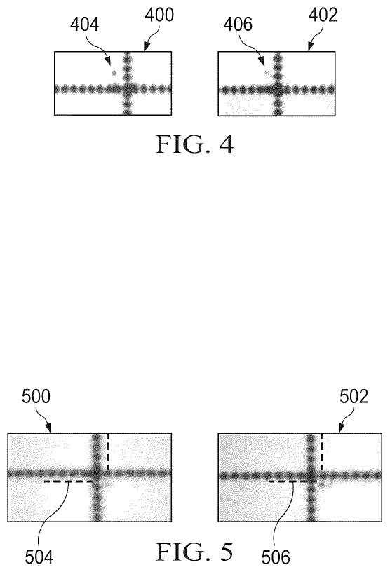

FIG. 4 are photographs 400 and 402 showing top views of respective splash detection wafers after performing typical two-pass stealth laser dicing methods. Each of the photographs 400 and 402 shows significant second-pass splash, shown at 404 and 406, respectively, at over 20 μm from the baseline.

FIG. 5 are photographs 500 and 502 showing examples of top views of respective splash detection wafers after performing three-pass stealth laser dicing methods, such as shown in FIG. 2. In FIG. 5, dashed lines 504 and 506 show second pass offset for the target positions of the second-pass laser beam pulses. For example, the second-pass offset can range from approximately 1 μm to approximately 5 μm. Additionally, the third-pass offset (not shown) can range from approximately 2 μm to approximately 5 μm, such as in the opposite direction from the base line. As a result of the three-pass stealth laser dicing method, the maximum splash is reduced to approximately 12.7 μm compared to FIG. 2.

FIG. 6 is a photograph 600 showing a side sectional view of a wafer after laser dicing according to one of the approaches described herein (see, e.g., FIGS. 2 and 3). The dark line extending across the wafer, shown at 602, is a result of the proposed two- or three-pass stealth laser dicing method described herein. The dark line 602 shows the side wall surface is not straight at that position because light reflection conditions are different for upper and lower surfaces, which demonstrates the offset described herein. The downside portion of the silicon wafer can be used to help prevent splash laser energy from reaching the active side (e.g., bottom surface) of the wafer. FIG. 6 also shows a modified region 604, such as the third stealth dicing region (e.g., modified region 206 or 310). Thus, the region 604 can be implemented with a lateral offset, which can reduce interaction between the final-pass laser energy with the crack line formed during the preceding one or two passes.

In view of the foregoing structural and functional features described above, a method is shown in FIG. 7. While the method of FIG. 7 is shown and described as executing serially, systems and methods described herein are not limited by the illustrated order, as some aspects could occur in different orders, multiple times and/or concurrently from that described herein.

FIG. 7 is a flow diagram illustrating an example method 700 for performing stealth laser dicing of a semiconductor substrate. The method can be implemented using the system 100 of FIG. 1. Accordingly, the method also refers to FIG. 1. For example, the system includes a laser system 122 arranged and configured to direct a focused laser beam at a first surface of the substrate, such as can be a top surface of a wafer that is free of active circuitry. The semiconductor substrate thus can include a plurality of semiconductor die having active circuitry at a second surface that are separated by respective scribe streets. The method 700 further can be used to perform two-pass or three-pass stealth laser dicing for wafer as described herein (see, e.g., FIGS. 2-6).

At 702, the method includes directing a first laser beam (e.g., an IR laser beam provided by laser module 124) at a surface of a semiconductor substrate with an entry point along a scribe street thereof. The first pass laser beam can be a pulsed laser that is focused inside the substrate to form a first modified region. An embedded crack can also be formed responsive to the first laser beam. The embedded crack can extend from the first modified region along a direction orthogonal to the surface (e.g., along a dicing direction) and have a length that is less than a thickness of the substrate.

At 704, the method includes directing a second laser beam (e.g., a pulsed laser) at the surface focused to have a second focal point inside the substrate to form a second modified region. The focal point and resulting second modified region within the substrate are offset from the first modified region in a later direction orthogonal to a scan direction of the laser beam along the scribe street. A second crack can also be formed responsive to the second laser beam, such as aligned with and thus extending the first crack in a direction toward the surface. In one example, the second laser beam is provided in a second pass of the laser following the a first pass, in which the first laser beam is provided in a first pass of the laser, such as described with respect to FIG. 2. In another example, the second laser beam is provided in the same pass as the first laser beam (e.g., a multi-beam pass), such as described with respect to FIG. 3.

At 706, a third laser beam is directed at the surface focused to have a third focal point inside the substrate to form a third modified region. The third modified region is offset from each of the first and second modified regions. The third laser beam further can form a third crack, which is offset from the first crack in a direction that is orthogonal to a scan direction of the laser beam.

As a further example, the surface at which the laser beams are directed is a first surface of the semiconductor substrate, and the first crack extends from a modified internal region to a second surface of the semiconductor substrate opposite the first surface. For example the opposite surface can include active circuitry for the die. The second crack can be an extension of the first crack, and the first and third cracks form a zigzag-shaped crack extending between the first and second surfaces of the substrate.

Additionally, the first modified region can be closer to the second surface than to the first surface. The third modified region can be closer to the first surface than to the second surface, and the second modified region thus resides between the first and third modified regions. In an example, prior to starting the method 700, positioning the second surface of the semiconductor substrate on a tape material. After performing the method 700, the plurality of die can be separated from each other during a separating process, such as by using an expander that expands the tape material. Backend processing can then be performed to package the respective die.

In this description, the term “couple” or “couples” means either an indirect or direct connection. Thus, if a first device couples to a second device, that connection may be through a direct connection or through an indirect connection via other devices and connections. For example, if device A generates a signal to control device B to perform an action, then: (a) in a first example, device A is coupled to device B; or (b) in a second example, device A is coupled to device B through intervening component C if intervening component C does not alter the functional relationship between device A and device B, so device B is controlled by device A via the control signal generated by device A.

Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof. Furthermore, a circuit or device described herein as including certain components may instead be configured to couple to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor wafer and/or integrated circuit (IC) package) and may be configured to couple to at least some of the passive elements and/or the sources to form the described structure, either at a time of manufacture or after a time of manufacture, such as by an end user and/or a third party.

The recitation “based on” means “based at least in part on.” Therefore, if X is based on Y, X may be a function of Y and any number of other factors.

Modifications are possible in the described embodiments, and other embodiments are possible, within the scope of the claims.

What is claimed is:

1. A method comprising:
directing a first laser beam at a surface of a semiconductor substrate with an entry point along a scribe street thereof, wherein the first laser beam is focused inside the substrate to form a first modified region, which is offset from a second modified region in a direction orthogonal to a scan direction of the first laser beam, and a first crack extending between the second modified region and the first modified region along a direction orthogonal to the surface; and
directing a second laser beam at the surface focused to have a second focal point inside the substrate to form a third modified region, which is offset from the first and second modified regions in a direction orthogonal to the scan direction of the second laser beam, and a second crack extending from the third modified region to the surface in a direction that is orthogonal to a scan direction of the second laser beam, the first and second cracks forming a zigzag-shaped crack within the substrate along the scribe street.

2. The method of claim 1, wherein the surface is a first surface and the substrate is a semiconductor wafer having a second surface opposite from the first surface, the first and second cracks extending between the first and second surfaces of the substrate.

3. The method of claim 2, wherein the first crack comprises an extension of a third crack extending from the second modified region, and the first crack is aligned with and follows the same direction as the third crack, wherein the third crack is formed during a first pass, which includes directing the first laser beam, or during a pass before the first pass.

4. The method of claim 2, wherein:
the second modified region is formed before the first modified region,
the first modified region is formed before the third modified region,
the second modified region is closer to the second surface than to the first surface, and
the third modified region is closer to the first surface than to the second surface.

5. The method of claim 2, wherein the substrate includes a plurality of semiconductor die having active circuitry at the second surface that are separated by respective scribe streets.

6. The method of claim 5, further comprising:
positioning the second surface of the substrate on a tape material; and
using an expander to expand the tape material and separate the plurality of semiconductor die.

7. A semiconductor die produced according to the method of claim 6, the semiconductor die including at least one side surface between the first and second surfaces, the at least one side surface including a textured pattern based on the zigzag-shaped crack formed within the substrate.

8. The method of claim 1, wherein the offset of the third modified region is offset relative to the scan direction in the same direction as the offset of the first modified region.

9. The method of claim 1, wherein the offset of the third modified region is offset relative to the scan direction in a direction opposite to a direction that the first modified region is offset.

10. The method of claim 9, wherein:
a center of the first modified region is offset from a center of the second modified region by a distance that ranges from 1 μm to 5 μm, and
a center of the third modified region is offset from a center of the second modified region by a distance that ranges from 3 μm to 6 μm.

11. A method comprising:
directing a first laser beam at a surface of a semiconductor substrate with an entry point along a scribe street thereof, wherein the first laser beam is focused inside the substrate to form a first modified region and an embedded first crack extending from the first modified region along a direction orthogonal to the surface and having a length that is less than a thickness of the substrate;
directing a second laser beam at the surface focused to have a second focal point inside the substrate to form a second modified region, which is offset from the first modified region in a direction orthogonal to a scan direction of the second laser beam, and a second crack extending the first crack toward the surface; and
directing a third laser beam at the surface focused to have a third focal point inside the substrate to form a third modified region, which is offset from the first and second modified regions, and a third crack and offset from the first crack in a direction that is orthogonal to a scan direction of the third laser beam.

12. The method of claim 11, wherein:
the surface is a first surface of the substrate, and the first crack extends from the first modified region to a second surface of the substrate opposite the first surface, and
the second crack is an extension of the first crack, and the first and third cracks form part of a zigzag-shaped crack through the substrate between the first and second surfaces of the substrate.

13. The method of claim 12, wherein:
the first modified region is closer to the second surface than to the first surface,
the third modified region is closer to the first surface than to the second surface, and
the second modified region resides between the first and third modified regions.

14. The method of claim 12, wherein the substrate includes a plurality of semiconductor die having active circuitry at the second surface that are separated by respective scribe streets.

15. The method of claim 14, further comprising:
positioning the second surface of the substrate on a tape material; and
separating the plurality of semiconductor die during a separating process using an expander that expands the tape material.

16. A semiconductor die produced according to the method of claim 15, the semiconductor die including at least one side surface between the first and second surfaces, the at least one side surface including a textured pattern based on the zigzag-shaped crack formed within the substrate.

17. The method of claim 11, wherein the third modified region is offset from the first modified region in a direction that is different from a direction that the second modified region is offset from the first modified region.

18. The method of claim 11, wherein:
a center of the second modified region is offset from a center of the first modified region by a distance that ranges from 1 μm to 5 μm, and
a center of the third modified region is offset from a center of the first modified region by a distance that ranges from 3 μm to 6 μm.

19. A system comprising:
a stage configured to hold at least one semiconductor wafer having first and second surfaces, the wafer including a plurality of semiconductor die having active circuitry at the second surface separated by respective scribe streets;
a laser system having a laser module supported above the stage, the laser module configured to direct a pulsed laser beam toward the stage; and
a control system coupled to the stage and the laser system, the control system configured to:
control the laser system and the stage to direct a first laser beam at the first surface with an entry point along a particular scribe street thereof and focused inside the wafer to form a first modified region and an embedded crack extending from the first modified region along a direction orthogonal to the second surface;
control the laser system and the stage to direct a second laser beam at the first surface along the particular scribe street focused to have a second focal point inside the wafer to form a second modified region, which is offset from the first modified region in a direction orthogonal to a scan direction of the second laser beam, and a second crack being an extension of the first crack toward the first surface; and
control the laser system and the stage to direct a third laser beam at the first surface along the particular scribe street focused to have a third focal point inside the wafer to form a third modified region, which is offset from the first and second modified regions, and a third crack, which offset from the first crack in a direction that is orthogonal to a scan direction of the third laser beam.

20. The system of claim 19, wherein:
the first and third cracks form a zigzag-shaped crack through the wafer extending between the first and second surfaces of the wafer,
the first modified region is closer to the second surface than to the first surface,
the third modified region is closer to the first surface than to the second surface, and
the second modified region resides between the first and third modified regions.

21. A semiconductor die comprising:
a first side surface;
a second side surface opposite the first side surface;
sidewall surfaces between the top and bottom side surfaces, in which a respective sidewall surface includes first and second sidewall portions, the first sidewall portion extending from the first side surface along a direction orthogonal to the first surface to an intermediate location between the first and second side surfaces, and the second sidewall portion being laterally offset and extending from the intermediate location to the second side surface along the direction orthogonal to the first surface.

22. The semiconductor die of claim 21, wherein the first and second sidewall portions provide a zigzag-shaped sidewall surface between the first and second side surfaces.

23. The semiconductor die of claim 21, wherein the first sidewall portion is laterally offset from second sidewall portions by a distance ranging from 1 μm to 5 μm.

24. The semiconductor die of claim 21, wherein each of the sidewall surfaces includes respective first and second sidewall portions, in which each first sidewall portion extends from the first side surface along a direction orthogonal to the first surface to an intermediate location between the first and second side surfaces, and each second sidewall portion is laterally offset and extends from the intermediate location to the second side surface along the direction orthogonal to the first surface to provide zigzag-shaped sidewall surfaces between the first and second side surfaces.
